(19) United States
(12) Patent Application Publication
(10) Pub. No.: US 2024/0222469 A1
(43) Pub. Date: Jul. 4, 2024

(54) TRANSISTOR IN A SILICON CARBIDE LAYER AND A TRANSISTOR IN A GALLIUM NITRIDE LAYER IN A CASCODE DESIGN

(71) Applicant: Intel Corporation, Santa Clara, CA (US)

(72) Inventors: Abhishek Anil SHARMA, Portland, OR (US); Han Wui THEN, Portland, OR (US); Wilfred GOMES, Portland, OR (US); Tahir GHANI, Portland, OR (US); Anand S. MURTHY, Portland, OR (US); Sagar SUTHRAM, Portland, OR (US); Pushkar RANADE, San Jose, CA (US)

(21) Appl. No.: 18/089,966

(22) Filed: Dec. 28, 2022

(51) Int. Cl. H01L 29/66; H01L 29/16; H01L 29/20

(52) U.S. Cl. CPC H01L 29/66462; H01L 29/1608; H01L 29/2003; H01L 29/66893

(57) ABSTRACT

Embodiments described herein may be related to apparatuses, processes, systems, and/or techniques for fabricating semiconductor packages that use high voltage transistors within a SiC layer that are coupled with one or more transistors in one or more other layers in a cascode format in order to switch the high voltage transistors in the SiC layer using low voltages. Other embodiments may be described and/or claimed.

### FIELD

Embodiments of the present disclosure generally relate to the field of semiconductor manufacturing, and in particular to packages that include transistors in a silicon carbide (SiC) layer coupled with transistors in an adjacent gallium nitride (GaN) layer.

### BACKGROUND

Continued growth in virtual machines, cloud computing, and portable devices will continue to increase the demand for high density transistors within chips and packages. This is particularly true with compute dies that are interacting with large amounts of memory for high bandwidth (HBW) computing where increased amounts of power may be required for operation.

### BRIEF DESCRIPTION OF THE DRAWINGS

FIGS. 1A-1B show cross-section side views of diagrams of a semiconductor package that include a silicon carbide (SiC) layer, a gallium nitride (GaN) layer, and a silicon (Si) layer proximate to each other, in accordance with various embodiments.

FIG. 2 shows an example of a GaN transistor and a Si transistor in a cascode design.

FIGS. 3A-3B illustrate diagrams of different structures of a three-stage cascode design, in accordance with various embodiments.

FIG. 4 shows an embodiment of a two-stage transistor cascode design with a driver, in accordance with various embodiments.

FIG. 5 shows examples of diagram of a transistor in a SiC layer and a transistor in a GaN layer where portions of the diagram may be mapped to a package that includes a SiC layer and a GaN layer, in accordance with various embodiments.

FIGS. 6A-6G show example configurations of SiC layers coupled with other layers in a package, in accordance with various embodiments.

FIG. 7 illustrates a side view of a diagram of a wafer scale engine (WSE) that includes Zetta memory that is powered by high voltage input that is converted using devices within a SiC layer coupled with devices within a GaN layer, in accordance with various embodiments.

FIG. 8 illustrates an example process for creating a package that includes a transistor in a SiC layer and a transistor in a GaN layer in a cascode design, in accordance with various embodiments.

FIG. 9 illustrates a computing device in accordance with one implementation of the invention.

FIG. 10 illustrates an interposer that includes one or more embodiments of the invention.

FIG. 11A illustrates a computing device in accordance with one implementation of an embodiment of the present disclosure.

FIG. 11B illustrates a processing device in accordance with one implementation of an embodiment of the present disclosure.

### DETAILED DESCRIPTION

Embodiments described herein may be related to apparatuses, processes, systems, and/or techniques for fabricating semiconductor packages that use a SiC layer that is coupled with another layer that may include, for example but not limited to, silicon (Si), germanium (Ge), nitrogen (N), gallium (Ga), arsenic (As), silicon germanium (SiGe), gallium nitride (GaN), SiC, or gallium arsenide (GaAs). In embodiments, the SiC layer may be an active layer that includes a transistor that is coupled with another transistor that may be in a second layer next to the SiC layer. In embodiments, the second layer may include GaN. In embodiments, the transistor in the SiC layer and the transistor in the second layer may be in a cascode design configuration. In embodiments, the SiC layer may be coupled with the second layer using fusion bonding, hybrid bonding, layer transfer, and/or bump and island formation techniques.

In other embodiments, a third layer may be proximate to the second layer, and may include a transistor that is electrically coupled with the transistor in the second layer and/or electrically coupled with the transistor in the SiC layer. In embodiments, the third layer may be a Si layer. In embodiments, the transistors in the SiC layer, the second layer, and the third layer may be in a cascode design.

In embodiments, the transistor in the SiC layer may have a high voltage difference between its source and its drain when it is OFF. When the transistor is on, a large amount of current may flow through the transistor and the voltage difference between its source and drain would be small. In embodiments, the transistors in the second layer or the third layer may be lower-voltage transistors and when used in a cascode configuration with the transistor in the SiC layer, are able to control or actuate the transistor in the SiC layer. In particular, lower voltage transistors act like a switch that may be used to turn the high-voltage transistors in the SiC layer on and off, thus controlling high current flow through the transistor in the SiC layer during the on-state, and withstand a high voltage during the off-state.

Higher voltage transistors, for example SiC transistors, do not turn on or off as steeply as Si and GaN transistors. However, Si transistors are typically used for lower voltages<20V because its performance suffers when its geometry is sized for high voltage operation. GaN transistors are rather versatile, able to handle extreme fast switching (>1 MHz to ˜GHz) at low voltages of <50V to high voltages up to several hundred volts. The SiC transistors may handle large voltages or small voltages, however to actuate these transistors, a high-voltage of ˜20V for e.g., is needed. In embodiments, a lower voltage transistor, for example a Si transistor or a GaN transistor, may provide a high-voltage to a gate of the SiC transistor in order to actuate the transistor.

In embodiments, high voltage may appear between a source and a drain of a SiC transistor without causing a failure within the SiC transistor, unlike a Si transistor where a high voltage between the source and the drain may cause the silicon in the channel to break down and the device to fail. In embodiments, using lower-voltage Si transistors and/or GaN transistors to control very high voltage, high-current transistors such as a SiC transistor, may result in more efficient power usage for the package. This is due to the large energy consumption of a SiC transistor if it was switched by other SiC transistors, where the energy consumed is based on CV². SiC transistors are also typically slower in switching speed than lower voltage Si and/or GaN transistors.

In some embodiments, transistors in a SiC layer may be coupled with transistors in a GaN layer and may be used to step down high-voltages, e.g. greater than 1 kV, provided to the package to 1-1.8 V for use by electrical components within the package. By providing high voltages to the package, greater electrical power is provided to operate a very large number of components, such as processor chips or memory within or coupled with the package.

In embodiments, the devices in the SiC layer may be used to initially step down a higher voltage, e.g. greater than 1 kV, on one side of the SiC layer to a medium voltage, e.g. 200 V, on the other side of the SiC layer that is next to a GaN layer. Devices in the GaN layer may be used to further step down, in multiple stages, the medium voltage of 200 V to a lower voltage, for example 1-1.8 V, which may then be used by chips and other devices within the package. In embodiments, by using devices within the SiC and GaN layers to step down voltages from an initial high-voltage, a far greater amount of power may be provided to the package as opposed to legacy packages that only receive voltages between 1-1.8 V. In embodiments, a high voltage source may be provided through bumps at a side of the package.

In embodiments, a silicon layer may be coupled with the GaN layer, where the silicon layer includes transistors or other devices that may be used to provide signal processing. In some embodiments, the SiC layer may be directly coupled with the silicon layer.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

In embodiments, high-Tc conductors are utilized for global routing. Implementation of embodiments described herein can include the presence of such materials in a metal layer and/or at the package level. Implementation of embodiments described herein can include the fabrication of inductors and/or through silicon vias (TSVs) with the same. Implementation of embodiments described herein can include fabrication of a separate metal stack (bonded or monolithic) for custom routing of finished product wafers. Implementation of embodiments described herein can include the introduction of high Tc superconductors (single crystal or deposited—atomic layer deposition (ALD) and/or chemical vapor deposition (CVD) may be used to reduce the IR drop across long distances including between die stitching.

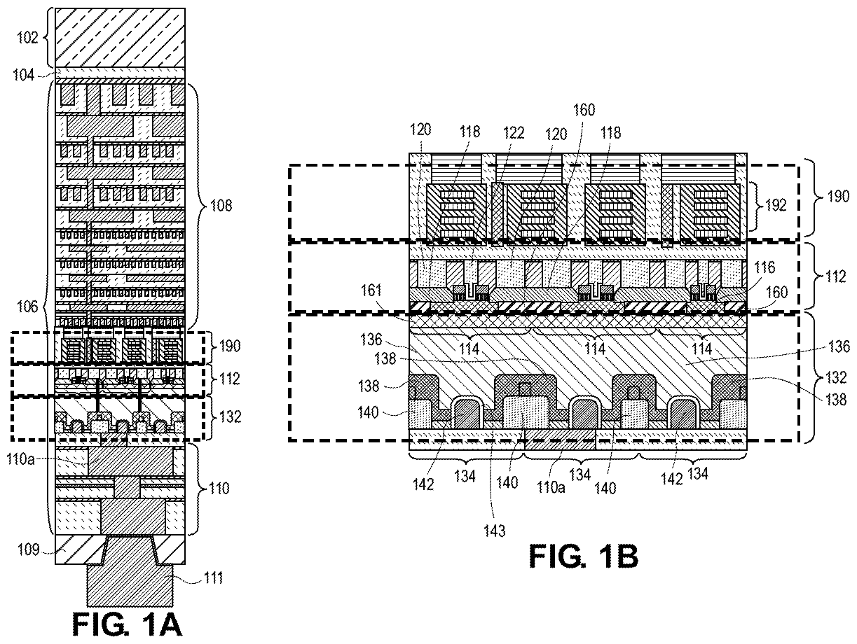

FIGS. 1A-1B show various cross-section side views of diagrams of a semiconductor package that include a silicon carbide (SiC) layer, a gallium nitride (GaN) layer, and a silicon (Si) layer proximate to each other, in accordance with various embodiments.

FIG. 1A shows an embodiment that is a side view that shows a carrier wafer 102 that is bonded to a package 106 using an adhesive 104. The package 106 may include front side routing layers 108, which may include traces and conductive vias used to route low-voltage power and/or signals, e.g. 1-1.8 V. The package 106 may also include back side routing layers 110, which may include power routings and conductive vias, that may route high-voltage power, e.g. handle voltage sources that are greater than 1 kV.

In embodiments, a Si layer 190 may be electrically coupled with and below the front side routing layers 108, and may include various devices (described in FIG. 1B). The GaN layer 112 may be below the Si layer 190 and various devices (described in FIG. 1B) within the GaN layer 112 may be electrically coupled with the Si layer 190. A SiC layer 132 may be between the GaN layer 112 and the back side routing layers 110, and various devices (described in FIG. 1B) formed within the SiC layer 132 may be electrically coupled with one or more of the routing elements within the back side routing layers 110, for example high-voltage connector 110a. In embodiments, a bump 111, which may include a solder ball or a copper pad, may be electrically coupled with the back side routing layers 110 to provide high-voltage power from an outside source. In embodiments, the bump 111 may be surrounded by a dielectric 109.

FIG. 1B illustrates an enlarged view of the Si layer 190, the GaN layer 112 and the SiC layer 132 of FIG. 1A. In embodiments, the Si layer 190 may include a plurality of devices 192 that include silicon. Examples of the devices 192 may include transistors. In embodiments, the GaN layer 112 may include a plurality of transistors 114 that are on a GaN material 116. Each of the transistors 114 may include a doped GaN region 118 onto which contacts 120 are coupled. A gate 122 may be between the various contacts 120. In embodiments, there may be one or more vias (not shown) between a contact 120 and the front side routing layers 108 of FIG. 1A to provide a lower voltage, for example between 1 and 1.8 V, to the front side routing layer 108. Note that in this embodiment, the transistors 114 are “face up,” with the contacts 120 and the gate 122 facing toward the front side routing layers 108 of FIG. 1A. In other embodiments, the transistors 114 may be in some other configuration or some other orientation. In embodiments, one or more back side power connectors 160, which may be PowerVias™, may electrically couple with the doped GaN region 118. In addition, there may be additional elements, such as interconnects, thru silicon vias and capacitors (not shown) within the GaN layer 112.

In embodiments, the SiC layer 132 may include a plurality of transistors 134 that are within a SiC material 136. The transistors 134 may include a doped region 138 onto which contacts 140 are coupled. A gate 142 may be formed between the contacts 140. In embodiments, the gate 142 may be a poly silicon gate that may be surrounded by another suitably doped semiconductor region 143. In embodiments, the gate 142 and/or the contacts 140 may be electrically coupled with the high-voltage connector 110a, that may be coupled with the back side routing layers 110 of FIG. 1A. Note that in this embodiment, the transistors 134 are “face down,” with contacts 140 and the gate 142 facing toward the back side routing layers 110 of FIG. 1A. In embodiments, this configuration may allow a more efficient, lower loss connection with the high-voltage connector 110a. In other embodiments, the transistors 134 may be in some other configuration or some other orientation. In addition, there may be additional elements, such as interconnects, thru silicon vias and capacitors (not shown) within the SiC layer 132. In embodiments, there may be a doped SiC region 161, which may have a N+ doping, within the SiC layer 132.

In embodiments, discussed further below, transistors 134 and the transistors 114 may be coupled in a cascode design. In embodiments, transistors that are part of devices 192 may also be coupled with the transistors 134 and the transistors 114 in a cascode design. In embodiments, this cascode design may allow transistors that are part of devices 192 that are at lower voltage and/or transistors 114 that are at lower voltage to switch higher-voltage transistors 134 in the SiC layer 132 on and off.

In embodiments, electrical connections 160 may electrically couple the transistors 134 within the SiC layer 132 with transistors 114 within the GaN layer 112. In embodiments, the electrical connections 160 may include vias that extend at least partially through the SiC layer 132 and are filled with a conductive material such as copper.

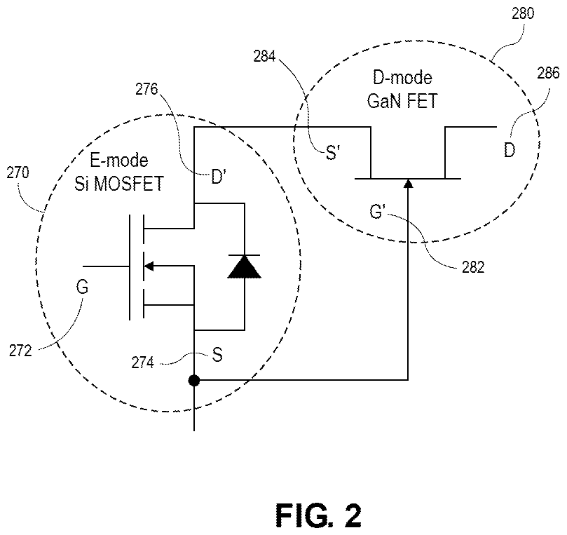

FIG. 2 shows an example diagram of a GaN transistor and a Si transistor in a cascode design. A high voltage transistor 280, which may be a GaN FET, may include a gate G′ 282, a source S′ 284, and a drain D 286, and may be electrically coupled with a low voltage transistor 270, which may be a Si MOSFET, which may be referred to as a Si CMOS FET, that may include a gate G 272, a source S 274 and a drain D′ 276. The source S 274 is electrically coupled with the gate G′ 282, and the drain D′ 276 is electrically coupled with the source S′ 284. In implementations, to actuate the high voltage transistor 280, a high voltage is needed at the gate G′ 282.

In this configuration, the low voltage transistor 270 may be used to control the high voltage transistor 280. For example, a zero voltage applied to gate G 272 will turn the low voltage transistor 270 off completely. As a result, the voltage differential between the source S 274 and the drain D′ 276 will be high, which would cause the voltage differential between the gate G′ 282, and the source S′ 284 to be drop below zero, thus below the threshold voltage of transistor 280. As a result, the high voltage transistor 280 will be switched off. When in off-state, the cascode configuration in FIG. 2 will be able to withstand a large voltage between the drain 286 and source 274.

However, if a voltage above the threshold voltage of transistor 270 is applied to gate G 272, then the low voltage transistor 270 will be turned on, and the voltage at the drain D′ 276 (equal to the potential at source S′ 284) would be pulled down to near zero (nearly the same potential as the source S 274). The potential at gate G′ 282 will be the same as the voltage at source S 274, and the source S′ 284. As a result, the high voltage transistor 280 will be switched on.

As a result, the voltage of gate G′ 282 did not need to be explicitly switched —instead, all of the changes in operation of the high voltage transistor 280 may be made by changing the voltage at gate G 272 of low voltage transistor 270.

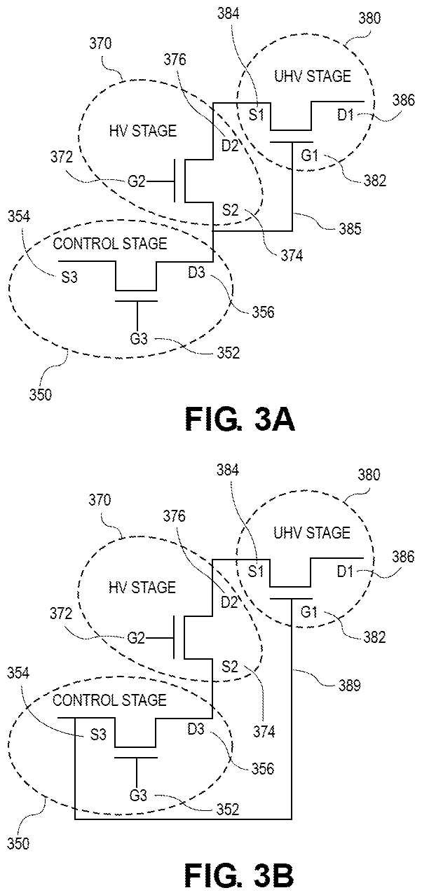

FIGS. 3A-3B illustrate diagrams of different structures of a three-stage cascode design, in accordance with various embodiments. FIG. 3A shows a control stage transistor 350 that includes a source S3 354, a drain D3 356, and a gate G3 352. In embodiments, the control stage transistor 350 may be implemented in silicon. In embodiments, the control stage transistor 350 may be electrically coupled with a high voltage (HV) stage transistor 370, which may include a gate G2 372, a source S2 374, and a drain D2 376. In embodiments, the drain D3 356 may be electrically coupled with the source S2 374. In embodiments, the HV stage transistor 370 may be implemented in GaN.

In embodiments, an ultra-high voltage (UHV) stage transistor 380 may be electrically coupled with the HV stage transistor 370. The UHV stage transistor 380 may include a source S1 384, a gate G1 382, and a drain D1 386. In embodiments, the UHV stage transistor 380 may be implemented in SiC. In embodiments, an electrical connection 385 may electrically couple the gate G1 382 and the source S2 374 and the drain D3 356. In embodiments the UHV stage transistor 380 may operate at a voltage that is greater than 1 kV, the HV stage transistor 370 may operate at a voltage that is less than 1 kV and greater than 5V, and the control stage transistor 350 may operate at a voltage that is less than 5V. FIG. 3B is similar to the three stage cascode design shown FIG. 3A. However, the gate G1 382 is electrically coupled with the source S3 354 through electrical connection 389.

In embodiments, the UHV stage transistor 380, the HV stage transistor 370 and/or the control stage transistor 350 may be implemented as a high electron mobility transistor (HEMT), a junction gate field effect transistor (JFET), metal oxide semiconductor high electron mobility transistor (MOSHEMT), or metal oxide semiconductor field-effect transistor (MOSFET).

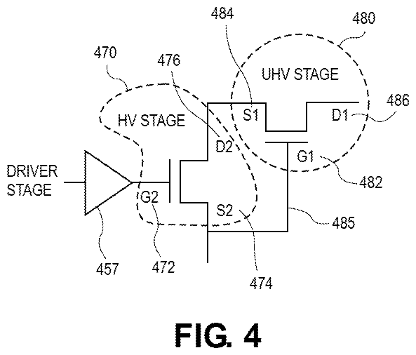

FIG. 4 shows an embodiment of a two-stage transistor cascode design with a driver, in accordance with various embodiments. FIG. 4, which may be similar to FIGS. 3A-3C, shows a HV stage transistor 470, which may include a gate G2 472, a source S2 474, and a drain D2 476. In embodiments, the HV stage transistor 470 may be implemented in GaN.

In embodiments, an UHV stage transistor 480 may be electrically coupled with the HV stage transistor 470. The UHV stage transistor 480 may include a source S1 484, a gate G1 482, and a drain D1 486. In embodiments, the UHV stage transistor 480 may be implemented in SiC. In embodiments the gate G1 482 may electrically couple with the source S2 474 using electrical connection 485, which may create the cascode design similar to the cascode design shown with respect to FIG. 2.

A driver 457 may be electrically coupled with the gate G2 472. In embodiments, the driver 457 may include multiple stages and blocks of circuits, typically, comprising pull-up and pull-down transistors that can be implemented with complementary n-channel and p-channel Si MOSFETs. Of all the semiconductors mentioned in this disclosure, silicon MOSFET is unique in that it offers high performing p-channel MOSFET. Such a p-channel in GaN and SiC are challenging and expensive to implement.

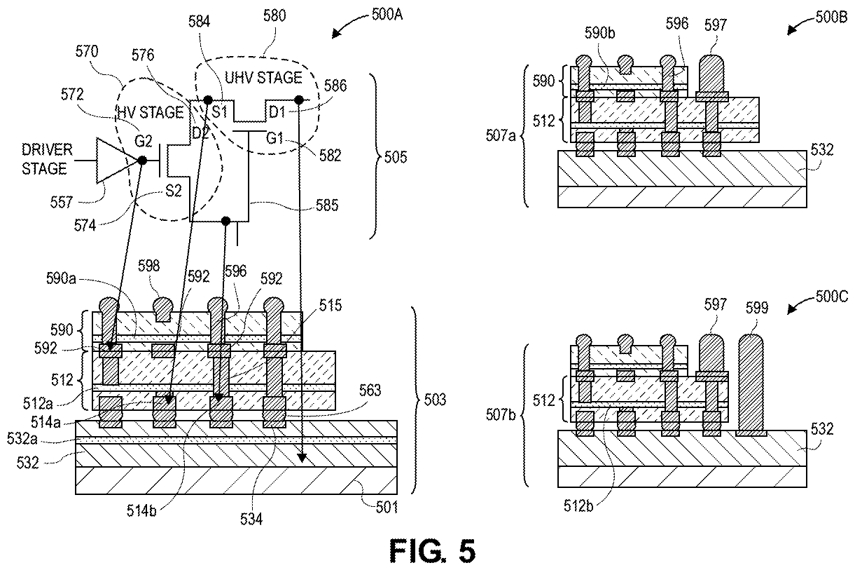

FIG. 5 shows examples of a diagram of a transistor in a SiC layer and a transistor in a GaN layer where portions of the diagram may be mapped to a package that includes a SiC layer and a GaN layer, in accordance with various embodiments. Diagram 500A shows a diagram 505, which may be similar to the diagram shown in FIG. 4. Diagram 505 includes a HV stage transistor 570, which may be similar to HV stage transistor 470 of FIG. 4, which may include a gate G2 572, a source S2 574, and a drain D2 576. In embodiments, the HV stage transistor 570 may be implemented in GaN.

In embodiments, an UHV stage transistor 580, which may be similar to UHV stage transistor 480 of FIG. 4, may be electrically coupled with the HV stage transistor 570. The UHV stage transistor 580 may include a source S1 584, a gate G1 582, and a drain D1 586. In embodiments, the UHV stage transistor 580 may be implemented in SiC. In embodiments the gate G1 582 may electrically couple with the source S2 574 using electrical connection 585, which may create the cascode design similar to the design shown with respect to FIG. 2. In embodiments, a driver 557, which may be similar to driver 457 of FIG. 4, may be electrically coupled with the gate G2 572.

Package 503 includes a SiC layer 532, which may be on a base wafer 501, includes electrical connections 534 that may couple with a GaN layer 512, which may include electrical connections 514a, 514b, that may electrically and physically couple with the electrical connections 534 using a BGA 563. In embodiments, a Si layer 590 with electrical connections 592 may directly electrically couple with GaN vias 515, which may be filled with copper or with some other conductive material, that extend through the GaN layer 512. In embodiments, the Si layer 590 may be hybrid bonded with the GaN layer 512, where the electrical connections 592 may be direct bonded to the GaN vias 515. In embodiments, a Si via 596 may electrically couple with an electrical connection 592, and couple with a corresponding connector 598 on a side of the Si layer 590. In embodiments, the corresponding connector 598 may be a solder ball.

In embodiments, a layer of SiC circuitry 532a may be within the SiC layer 532, a layer of GaN circuitry 512a may be in the GaN layer 512, and a layer of Si circuitry 590a may be within the Si layer 590. In embodiments, elements of the diagram 505 may map into corresponding locations in the package 503 as follows. All or part of the UHV stage transistor 580 may be within the layer of SiC circuitry 532a of the SiC layer 532. In embodiments, the drain D1 586 may electrically couple with electrical elements (not shown) within the base wafer 501. In embodiments, the source S1 584 may electrically couple with electrical connection 514a, and the electrical connection 585 that may create the cascode structure, may electrically couple with the electrical connection 514b.

In embodiments, all or part of the HV stage transistor 570 may be in the layer of GaN circuitry 512a of the GaN layer 512. In embodiments, the drain D2 576 may electrically couple with electrical connection 514a, and the source S2 574 may electrically couple with electrical connection 514b. In embodiments, all or part of the driver 557 may be in the layer of Si circuitry 590a of the Si layer 590, and may be electrically coupled with the electrical connection 592.

Diagram 500B shows package 507a, which is an alternative embodiment of the package 503, where a copper pillar 597 may be used that extends from the GaN layer 512 next to but not through the Si layer 590. In embodiments, if the copper pillar 597, during operation, is at an extremely high voltage, for example greater than 1 kV, and if the copper pillar 597 were within the Si layer 590, there is a likelihood that the Si layer 590 may physically break down due to the high voltage. This may cause an electrical short, or may cause defects within the layer of Si circuitry 590b. However, because the copper pillar 597 does not come into contact with the Si layer 590, there is a reduced possibility of a silicon breakdown in the Si layer.

Diagram 500C shows package 507b, which is an alternative embodiment of the package 503, where a copper pillar 599 may be used that extends from the SiC layer 532 next to but not through the GaN layer 512. In embodiments if the copper pillar 599, during operation, is at an extremely high voltage, for example greater than 1 kV, and if the copper pillar 599 were within the GaN layer 512, there is a likelihood that the GaN layer 512 may break down due to the high voltage, which may cause an electrical short, or may cause defects within the layer of GaN circuitry 512b. However, because the copper pillar 599 does not come into contact with the GaN layer 512, there is a reduced possibility of a breakdown in the GaN layer.

In embodiments, a choice of whether to use copper pillar 597 of diagram 500B or to use copper pillar 599 of diagram 500C to provide a lower resistance path from 512 to a load die above 590 (not shown in FIG. 5). The resistance of the copper pillar 599 will be much lower than the Si via 596 path through 590.

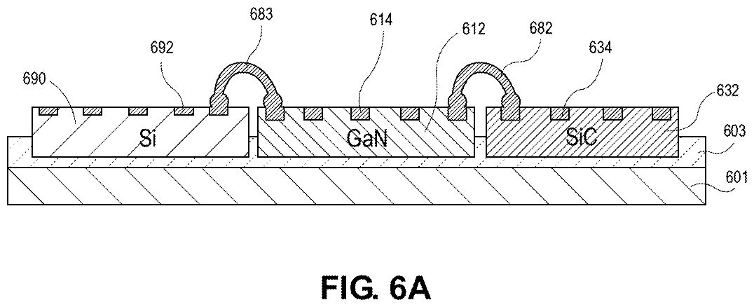

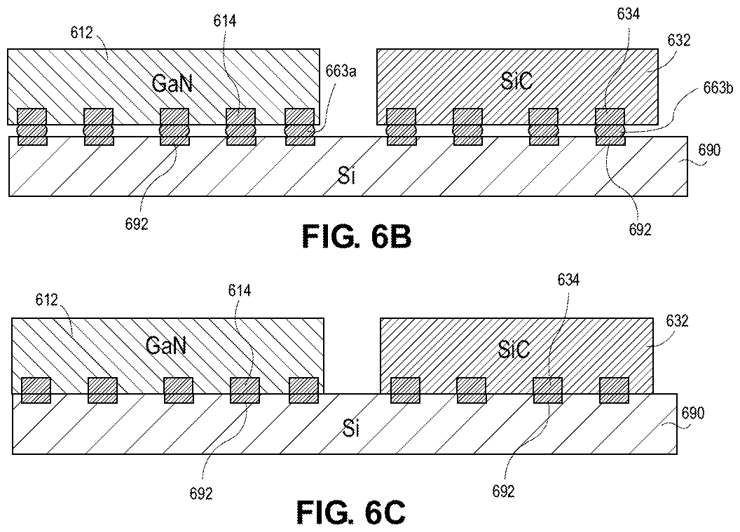

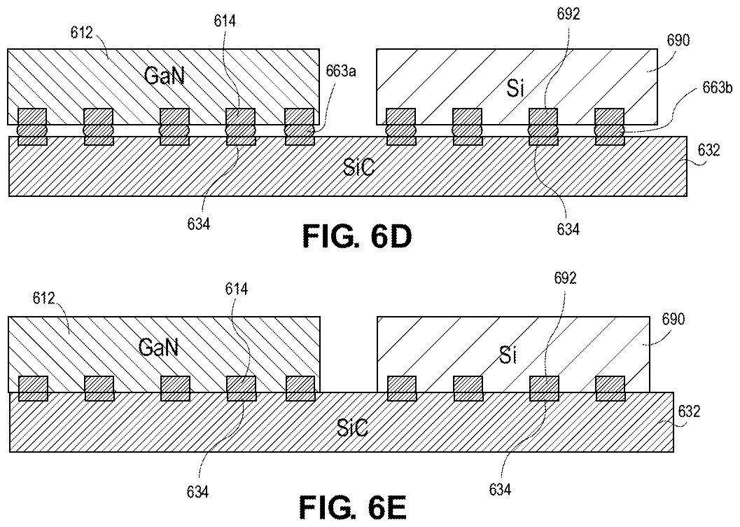

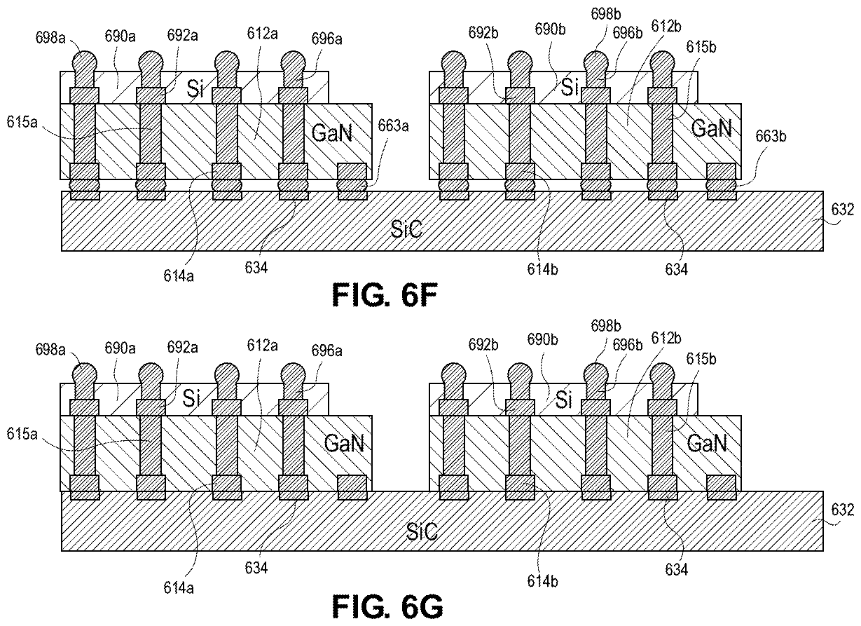

FIGS. 6A-6G show example configurations of SiC layers coupled with other layers in a package, in accordance with various embodiments. The examples shown in FIGS. 6A-6G are meant to be illustrative of embodiments, which may be similar to package 503 of FIG. 5, but are not an exhaustive list. FIG. 6A shows a cross-section side view of an example a SiC layer 632 that include devices 634, represented as pads, which may be similar to SiC layer 132 and transistors 134 of FIGS. 1A-1B, or may be similar to SiC circuitry 532a of FIG. 5. A GaN layer 612 is shown that include devices 614, represented as pads, which may be similar to GaN layer 112 and transistors 114 of FIGS. 1A-1B, or may be similar to GaN circuitry 512a of FIG. 5. A Si layer 690 is shown that may include devices 692, represented as pads, which may be similar to Si layer 190 and devices 692 of FIGS. 1A-1B, or similar to Si circuitry 590a of FIG. 5.

The SiC layer 632, GaN layer 612, and Si layer 690 may be coupled with a substrate 601 using an underfill material 603. In implementations, devices 634 may be electrically coupled with devices 614 using wire bonding 682, and devices 614 may be electrically coupled with devices 692 using wire bonding 683. In this implementation, the various devices 634, 614, 692 are further away from each other than as shown in embodiments described herein. Wire bonds are resistive (they are longer and connect over farther distances between die), and present high parasitic inductances which leads to higher losses and signal integrity issues.

FIG. 6B shows a cross-section side view of an embodiment that includes a Si layer 690 that includes devices 692. In embodiments, a GaN layer 612 that include devices 614 may be physically and electrically coupled with the Si layer 690 using BGA 663a. A SiC layer 632 that includes devices 634 may be electrically and physically coupled with the Si layer 690 using BGA 663b. In embodiments, the BGA 663a, 663b may be micro bumps.

FIG. 6C shows a cross-section side view of the embodiment shown in FIG. 6B, but with the GaN layer 612 and the SiC layer 632 directly coupled with the Si layer 690 using hybrid bonding techniques. In this way, the devices 614 and the devices 634, represented as copper pads, are direct bonded to devices 692. This implementation may reduce the IR loss that a BGA, such as BGA 663a, 663b of FIG. 6B, would otherwise introduce.

FIG. 6D shows a cross-section side view of an embodiment that includes a SiC layer 632, which may be a base wafer, that includes devices 634. A GaN layer 612 that includes devices 614 may be electrically and physically coupled with the SiC layer 632 using BGA 663a. A Si layer 690, which may include devices 692, may be electrically and physically coupled with the SiC layer 632 using BGA 663b. In these embodiments, the SiC layer 632 may be coupled with a high voltage source, for example a voltage greater than 1 kV, with the devices 634 stepping down the received voltage to a lower voltage, for example 200 V, which may then be coupled with the GaN layer 612 for the devices 614 to further step down the voltage to a 1-1.8V range.

FIG. 6E shows a cross-section side view of the embodiment shown in FIG. 6D, except that the GaN layer 612 and the Si layer 690 are directly coupled with the SiC layer 632 using hybrid bonding techniques. In this way, the devices 614 and the devices 692, represented as copper pads, are direct bonded to the devices 634. This implementation may reduce the IR loss that a BGA, such as BGA 663a, 663b of FIG. 6D would otherwise introduce.

FIG. 6F shows a cross-section side view of an embodiment that includes a SiC layer 632, which may be a base wafer, that includes devices 634 and a first GaN layer 612a, which may include devices 614a, that may electrically and physically couple with the devices 634 using a BGA 663a. A second GaN layer 612b, which may include devices 614b, may electrically and physically couple with the devices 634 using a BGA 663b.

In embodiments, a first Si layer 690a with devices 692a may directly electrically couple with GaN vias 615a, that may be filled with copper or with some other conductive material, that extend through the first GaN layer 612a. In embodiments, the first Si layer 690a may be hybrid bonded with the first GaN layer 612a, where the devices 692a may be direct bonded to the GaN vias 615a. In embodiments, a Si via 696a may electrically couple with a device 692a, and couple with a corresponding connector 698a on a side of the first Si layer 690a. In embodiments, the corresponding connector 698a may be a solder ball.

In embodiments, a second Si layer 690b with devices 692b may directly electrically couple with GaN vias 615b, that may be filled with copper, that extend through the second GaN layer 612b. In embodiments, the second Si layer 690b may be hybrid bonded with the second GaN layer 612b, where the devices 692b may be direct bonded to the GaN vias 615b. In embodiments, a Si via 696b may electrically couple with devices 692b, and couple with a corresponding connector 698b on a side of the second Si layer 690b. In embodiments, the corresponding connector 698b may be a solder ball.

FIG. 6G shows a cross-section side view of the embodiment shown in FIG. 6F, except that the first GaN layer 612a and the second GaN layer 612b are directly coupled with the SiC layer 632 using hybrid bonding techniques. In this way, the devices 614a, 614b, represented as copper pads, are direct bonded to the devices 634. This implementation may reduce the IR loss that a BGA, such as BGA 663a and BGA 663b of FIG. 6F would otherwise introduce.

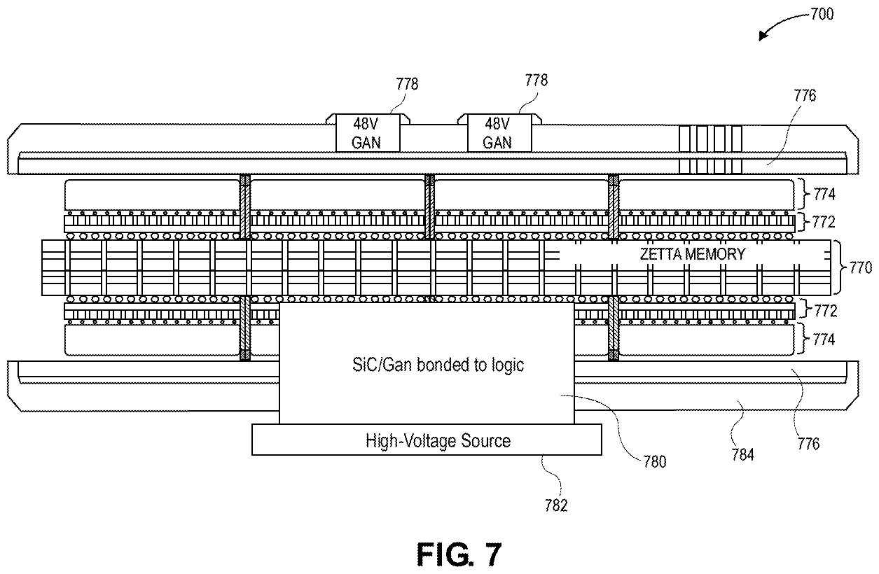

FIG. 7 illustrates a side view of a diagram of a wafer scale engine (WSE) that includes Zetta memory that is powered by high voltage input that is converted using devices within a SiC layer coupled with devices within a GaN layer, in accordance with various embodiments. Embodiments described herein may be used to enable Zetta scale computing. Zetta scale computing may include an extremely large number of computing devices within a package. For example, the computing devices together may provide on the order of 1021 floating-point operations per second (FLOPS). In addition, Zetta scale computing may also involve digital storage in the form of memory, for example DRAM memory, on the order of a zettabyte, or 1021 bytes within the package. The large number of computing devices and memory devices within a package may be implemented as a WSE, which may involve an entire wafer or large portions of a wafer, or multiple wafers coupled with each other, that include repeating patterns of compute circuitry on the wafers. This may be done rather than fabricating independent dies that are subsequently stitched together.

One characteristic of a WSE is that it may include components that are tens of millimeters apart. Electrically coupling such components may involve a significant IR drop. In order to mitigate this IR drop, high voltages, for example on the order of 1 kV, may be used to route power from one area of the wafer to another, which may then be converted to 1-1.8V using techniques described herein. In addition, a high-voltage supply may be used to provide significantly more power to a package. For example, a die on a wafer may consume on the order of 100 W. If there are 200 dies on a full wafer, that will requires 20 kW to power the entire wafer. And, if it is part of a WSE that may include multiple wafers bonded with each other, this power consumption will increase with each added wafer.

WSE 700 is an embodiment that includes a plurality of layers that may include a Zetta memory 770, which may include one or more wafers that may be coupled together, where each wafer includes a plurality of memory cells.

In embodiments, interconnect layers 772 may be on the top and the bottom of the Zetta memory 770, and input/output (I/O) layers 774 may be coupled, respectively, with the interconnect layers 772. In embodiments, the I/O layers 774 may include photonics circuitry (not shown). In embodiments, a heat sink 776 may be thermally coupled with the I/O layers 774 and/or the Zetta memory 770. In embodiments, a casing 784 may at least partially surround the Zetta memory 770, the interconnect layers 772, the I/O layers 774, and/or the heat sink 776.

In embodiments, power supplies 778, which may be electrically coupled with voltage source of less than 1 kV, may include devices within a GaN layer, which may be used to step the high voltage source down to 1-1.8 V for use by the Zetta memory 770 as discussed above with respect to FIGS. 1A-1B. In embodiments, a converter 780, which may include transistors within a GaN layer and transistors within a SiC layer that are coupled with each other to step down a voltage that may be greater than 1 kV from a high voltage source 782, down to 1-1.8 V, as discussed above with respect to FIGS. 1A-1B, for use by the Zetta memory 770. In embodiments, the GaN layer may be similar to GaN layer 112 of FIGS. 1A-1B, and the SiC layer may be similar to SiC layer 132 of FIGS. 1A-1B.

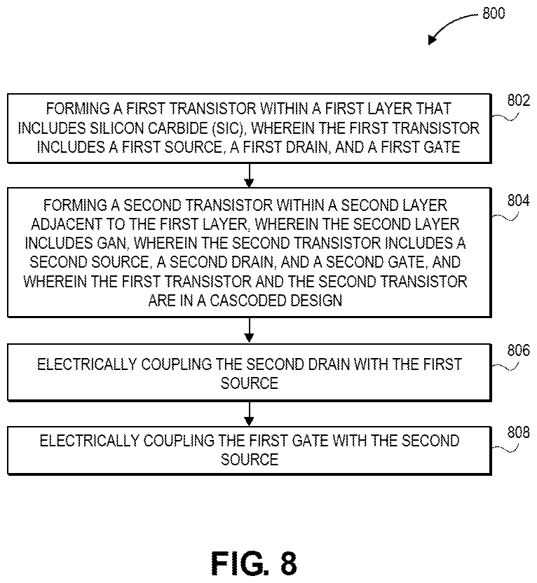

FIG. 8 illustrates an example process for creating a package that includes a SiC layer that is coupled with another layer that includes another material, in accordance with various embodiments. In embodiments, the process 800 may be performed using the techniques, processes, apparatus, and/or systems described herein, and in particular with respect to FIGS. 1A-7.

At block 802, the process may include forming a first transistor within a first layer that includes SiC, wherein the first transistor includes a first source, a first drain, and a first gate. In embodiments, the first transistor may be similar to transistor 134 and the first layer may be similar to the SiC layer 132 of FIG. 1B. In embodiments, the first source may be similar to source S1 384, the first drain may be similar to drain D1 386, and the first gate may be similar to gate G1 of FIG. 3A.

At block 804, the process may further include forming a second transistor within a second layer adjacent to the first layer, wherein the second layer includes GaN, wherein the second transistor includes a second source, a second drain, and a second gate, and wherein the first transistor and the second transistor are in a cascoded design. In embodiments, the second transistor may be similar to transistors 114 and the second layer may be similar to the GaN layer 112 of FIG. 1B. In embodiments, the second source may be similar to source S2 374, the second drain may be similar to drain D2 376, and the second gate may be similar to gate G2 372 of FIG. 3A.

At block 806, the process may further include electrically coupling the second drain with the first source. In embodiments, the electrical coupling may be similar to the diagram of FIG. 3A.

At block 808, the process may further include electrically coupling the first gate with the second source. In embodiments, the electrical coupling may be similar to electrical connection 385 of FIG. 3A.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

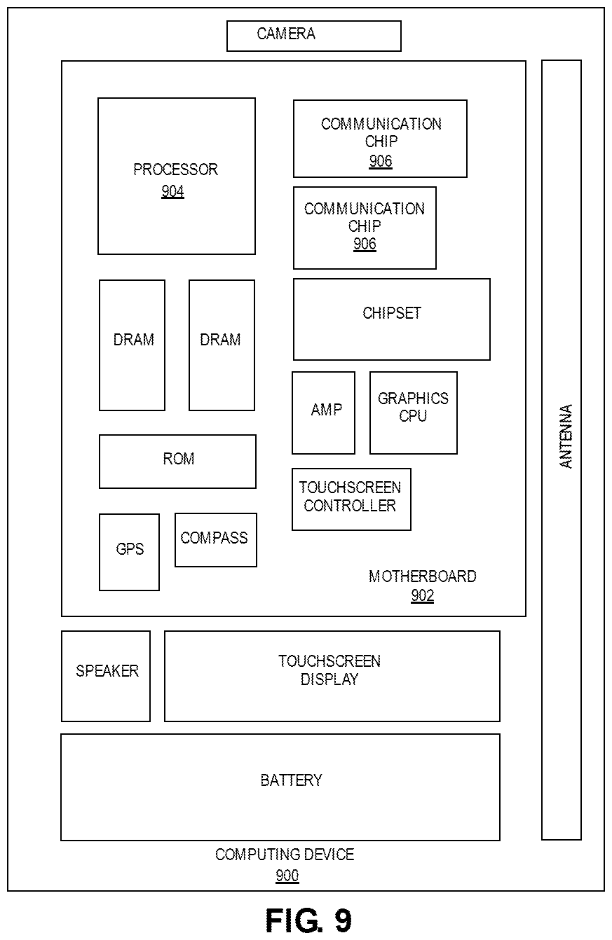

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip includes one or more devices, such as MOS-FET transistors built in accordance with implementations of the invention.

In further implementations, another component housed within the computing device 900 may contain an integrated circuit die that includes one or more devices, such as MOS-FET transistors built in accordance with implementations of the invention.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

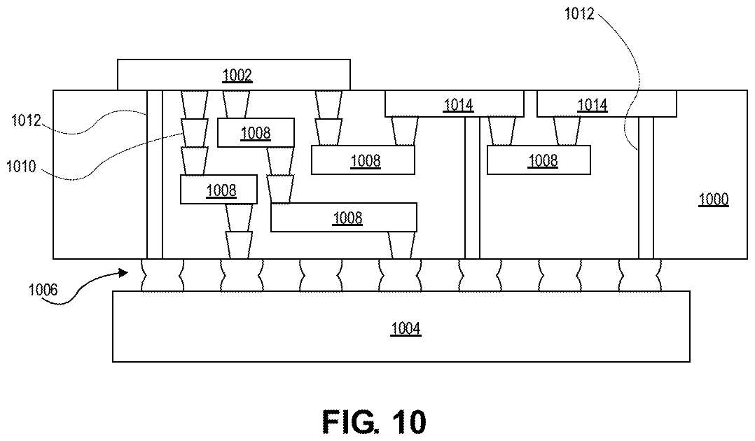

FIG. 10 illustrates an interposer 1000 that includes one or more embodiments of the invention. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer 1000 may be formed of alternate rigid or flexible materials that may include the same materials described above for use in a semiconductor substrate, such as silicon, germanium, and other group III-V and group IV materials.

The interposer 1000 may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the invention, apparatuses or processes disclosed herein may be used in the fabrication of interposer 1000.

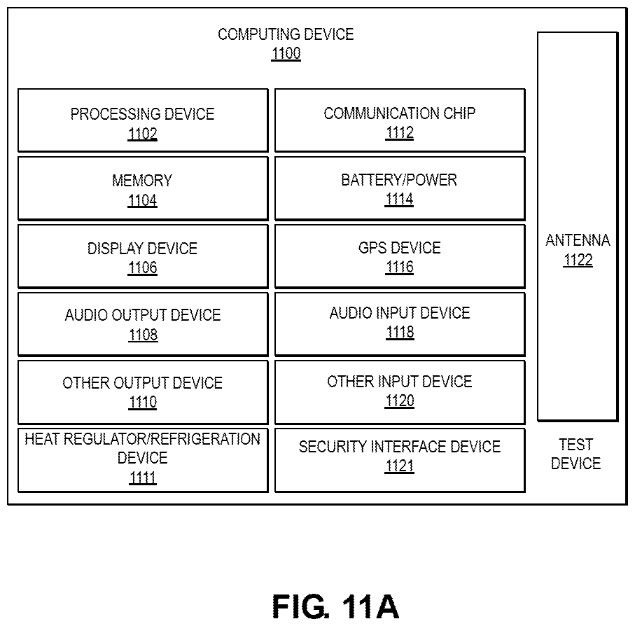

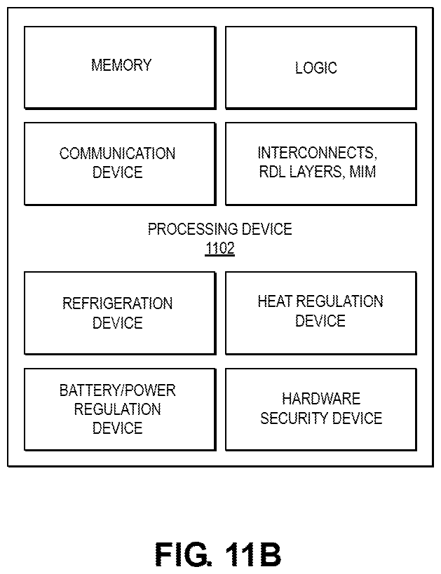

It is to be appreciated that structures described herein may be operated at a low temperature, e.g., in a range of −77 degrees Celsius to 0 degrees Celsius. In one embodiment, a heat regulator/refrigeration device is coupled to a common board having a device with structures such as those described herein coupled thereto, such as described below in association with FIG. 11A. In one embodiment, a heat regulator device and/or refrigeration device is included on a processing device having structures such as those described herein, such as described below in association with FIG. 11B.

FIG. 11A illustrates a computing device 1100 in accordance with one implementation of an embodiment of the present disclosure. The computing device 1100 houses a board. The board may include a number of components, including but not limited to a processing device 1102. The computing device 1100 can also include communication chip 1112. In one embodiment, the processing device 1102 is physically and electrically coupled to the board. In some implementations the communication chip 1112 is also physically and electrically coupled to the board. In further implementations, the communication chip 1112 is part of the processing device 1102.

Depending on its applications, computing device 1100 may include other components that may or may not be physically and electrically coupled to the board. These other components can include, but are not limited to, memory 1104, such as volatile memory (e.g., DRAM), non-volatile memory (e.g., ROM), or flash memory, an antenna 1122, a display device 1106, a battery/power 1114, an audio output device 1108, an audio input device 1118, a global positioning system (GPS) device 1116, an other output device 1110 (such as video output), and other input device 1120 (such as video input), a security interface device 1121, and/or a test device. In one embodiment, a heat regulation/refrigeration device 1111 is included and is coupled to the board, e.g., a device including actively cooled copper channels.

The communication chip 1112 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1112 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1112. For instance, a first communication chip 1112 may be dedicated to shorter range wireless communications such as Wi-Fi and Bluetooth and a second communication chip 1112 may be dedicated to longer range wireless communications such as GPS, EDGE, GPRS, CDMA, WiMAX, LTE, Ev-DO, and others.

The processing device 1102 of the computing device 1100 can include an integrated circuit die in a package. The processing device 1102 may include one or more structures, such as gate-all-around integrated circuit structures having ultra-high conductivity global routing, built in accordance with implementations of embodiments of the present disclosure. The term “processing device” may refer to any device or portion of a device that processes electronic data from registers and/or memory to transform that electronic data into other electronic data that may be stored in registers and/or memory.

FIG. 11B illustrates a processing device in accordance with one implementation of an embodiment of the present disclosure. Referring to FIG. 11B, an exemplary processing device 1102 includes a memory region, a logic region, a communication device region, an interconnects and redistribution layer (RDL) and metal-insulator-metal (MIM) region, a refrigeration device region, a heat regulation device region, a batter/power regulation device region and a hardware security device region. In one embodiment, the refrigeration device region and/or the heat regulation device region is a region including actively cooled copper channels.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs describe examples of various embodiments.

### EXAMPLES

Example 1 is an apparatus comprising: a first transistor, wherein a channel of the first transistor includes silicon (Si) and carbon (C), and wherein the first transistor includes a first source, a first drain, and a first gate; a second transistor, wherein the second transistor includes a second source, a second drain, and a second gate; and wherein the second source is electrically coupled with the first gate, and wherein the second drain is electrically coupled with the first source.

Example 2 includes the apparatus of example 1, wherein the second source is directly electrically coupled with the first gate, or wherein the second drain is directly electrically coupled with the first source.

Example 3 includes the apparatus of examples 1 or 2, wherein a material of a channel of the second transistor is different than a material of the channel of the first transistor.

Example 4 includes the apparatus of examples 1, 2, or 3, wherein a material of a channel of the second transistor includes a selected one or more of: Si, gallium (Ga), germanium (Ge), nitrogen (N), oxygen (O), carbon (C), phosphorous (P) or arsenic (As).

Example 5 includes the apparatus of example 4, wherein the material of the channel of the second transistor includes GaN.

Example 6 includes the apparatus of examples 1, 2, 3, 4, or 5, further comprising a third transistor, wherein the third transistor includes a third source, a third drain, and a third gate, wherein the third drain is electrically coupled with the second source.

Example 7 includes the apparatus of example 6, wherein the third source is electrically coupled with the first gate.

Example 8 includes the apparatus of examples 6 or 7, wherein a voltage applied to the third gate controls an electrical current between the first source and the first drain.

Example 9 includes the apparatus of examples 1, 2, 3, 4, 5, 6, 7, or 8, wherein the first transistor or the second transistor are a selected one of: a high electron mobility transistor (HEMT), a junction gate field effect transistor (JFET), metal oxide semiconductor high electron mobility transistor (MOSHEMT), or metal oxide semiconductor field-effect transistor (MOSFET).

Example 10 is an apparatus comprising: a first transistor, wherein a channel of the first transistor includes silicon (Si) and carbon (C), and wherein the first transistor includes a first source, a first drain, and a first gate; a second transistor, wherein the second transistor includes a second source, a second drain, and a second gate; a driver electrically coupled with the second gate of the second transistor; and wherein the second source is electrically coupled with the first gate, and wherein the second drain is electrically coupled with the first source.

Example 11 includes the apparatus of example 10, wherein the second source is directly electrically coupled with the first gate, or wherein the second drain is directly electrically coupled with the first source.

Example 12 includes the apparatus of examples 10 or 11, wherein a material of a channel of the second transistor includes a selected one or more of: Si, gallium (Ga), germanium (Ge), nitrogen (N), oxygen (O), carbon (C), phosphorous (P) or arsenic (As).

Example 13 includes the apparatus of example 12, wherein the material of the channel of the second transistor includes GaN.

Example 14 includes the apparatus of examples 12 or 13, wherein the driver includes a silicon CMOS FET.

Example 15 includes the apparatus of examples 12, 13, or 14, wherein a voltage from the driver applied to the second gate of the second transistor controls an electrical current between the first source and the first drain.

Example 16 includes the apparatus of examples 12, 13, 14, or 15, wherein the first transistor or the second transistor are a selected one of: a high electron mobility transistor (HEMT), a junction gate field effect transistor (JFET), metal oxide semiconductor high electron mobility transistor (MOSHEMT), or metal oxide semiconductor field-effect transistor (MOSFET).

Example 17 is a method comprising: forming a first transistor within a first layer that includes silicon (Si) and carbon (C), wherein the first transistor includes a first source, a first drain, and a first gate; forming a second transistor within a second layer adjacent to the first layer, wherein the second layer includes gallium (Ga) and nitrogen (N), wherein the second transistor includes a second source, a second drain, and a second gate, and wherein the first transistor and the second transistor are in a cascoded design; electrically coupling the second drain with the first source; and electrically coupling the first gate with the second source.

Example 18 includes the method of example 17, wherein the second layer includes Ga and N.

Example 19 includes the method of examples 17 or 18, further comprising: forming a third transistor within a third layer adjacent to the second layer, wherein the third transistor includes a third source, a third drain, and a third gate; and electrically coupling the third source with the first gate.

Example 20 includes the method of example 19, wherein electrically coupling the second drain with the first source, electrically coupling the first gate with the second source, and electrically coupling the third source with the first gate further include electrically coupling the second drain with the first source, electrically coupling the first gate with the second source, and electrically coupling the third source with the first gate using copper.

What is claimed is:

1. An apparatus comprising:
a first transistor, wherein a channel of the first transistor includes silicon (Si) and carbon (C), and wherein the first transistor includes a first source, a first drain, and a first gate;
a second transistor, wherein the second transistor includes a second source, a second drain, and a second gate; and
wherein the second source is electrically coupled with the first gate, and wherein the second drain is electrically coupled with the first source.

2. The apparatus of claim 1, wherein the second source is directly electrically coupled with the first gate, or wherein the second drain is directly electrically coupled with the first source.

3. The apparatus of claim 1, wherein a material of a channel of the second transistor is different than a material of the channel of the first transistor.

4. The apparatus of claim 1, wherein a material of a channel of the second transistor includes a selected one or more of: Si, gallium (Ga), germanium (Ge), nitrogen (N), oxygen (O), carbon (C), phosphorous (P) or arsenic (As).

5. The apparatus of claim 4, wherein the material of the channel of the second transistor includes GaN.

6. The apparatus of claim 1, further comprising a third transistor, wherein the third transistor includes a third source, a third drain, and a third gate, wherein the third drain is electrically coupled with the second source.

7. The apparatus of claim 6, wherein the third source is electrically coupled with the first gate.

8. The apparatus of claim 6, wherein a voltage applied to the third gate controls an electrical current between the first source and the first drain.

9. The apparatus of claim 1, wherein the first transistor or the second transistor are a selected one of: a high electron mobility transistor (HEMT), a junction gate field effect transistor (JFET), metal oxide semiconductor high electron mobility transistor (MOSHEMT), or metal oxide semiconductor field-effect transistor (MOSFET).

10. An apparatus comprising:
a first transistor, wherein a channel of the first transistor includes silicon (Si) and carbon (C), and wherein the first transistor includes a first source, a first drain, and a first gate;
a second transistor, wherein the second transistor includes a second source, a second drain, and a second gate;
a driver electrically coupled with the second gate of the second transistor; and
wherein the second source is electrically coupled with the first gate, and wherein the second drain is electrically coupled with the first source.

11. The apparatus of claim 10, wherein the second source is directly electrically coupled with the first gate, or wherein the second drain is directly electrically coupled with the first source.

12. The apparatus of claim 10, wherein a material of a channel of the second transistor includes a selected one or more of: Si, gallium (Ga), germanium (Ge), nitrogen (N), oxygen (O), carbon (C), phosphorous (P) or arsenic (As).

13. The apparatus of claim 12, wherein the material of the channel of the second transistor includes GaN.

14. The apparatus of claim 12, wherein the driver includes a silicon CMOS FET.

15. The apparatus of claim 12, wherein a voltage from the driver applied to the second gate of the second transistor controls an electrical current between the first source and the first drain.

16. The apparatus of claim 12, wherein the first transistor or the second transistor are a selected one of: a high electron mobility transistor (HEMT), a junction gate field effect transistor (JFET), metal oxide semiconductor high electron mobility transistor (MOSHEMT), or metal oxide semiconductor field-effect transistor (MOSFET).

17. A method comprising:
forming a first transistor within a first layer that includes silicon (Si) and carbon (C), wherein the first transistor includes a first source, a first drain, and a first gate;
forming a second transistor within a second layer adjacent to the first layer, wherein the second layer includes gallium (Ga) and nitrogen (N), wherein the second transistor includes a second source, a second drain, and a second gate, and wherein the first transistor and the second transistor are in a cascoded design;
electrically coupling the second drain with the first source; and
electrically coupling the first gate with the second source.

18. The method of claim 17, wherein the second layer includes Ga and N.

19. The method of claim 17, further comprising:
forming a third transistor within a third layer adjacent to the second layer, wherein the third transistor includes a third source, a third drain, and a third gate; and
electrically coupling the third source with the first gate.

20. The method of claim 19, wherein electrically coupling the second drain with the first source, electrically coupling the first gate with the second source, and electrically coupling the third source with the first gate further include electrically coupling the second drain with the first source, electrically coupling the first gate with the second source, and electrically coupling the third source with the first gate using copper.
